(19) United States
(12) Patent Application Publication
(10) Pub. No.: US 2026/0163331 A1
(43) Pub. Date: Jun. 11, 2026

(54) OPTICAL ELEMENT, OPTICAL DEVICE, AND METHOD FOR PRODUCING OPTICAL ELEMENT

(71) Applicant: INTER-UNIVERSITY RESEARCH INSTITUTE CORPORATION NATIONAL INSTITUTES OF NATURAL SCIENCES, Mitaka-shi, Tokyo (JP)

(72) Inventor: Takunori TAIRA, Okazaki-shi, Aichi (JP)

(73) Assignee: INTER-UNIVERSITY RESEARCH INSTITUTE CORPORATION NATIONAL INSTITUTES OF NATURAL SCIENCES, Mitaka-shi, Tokyo (JP)

(21) Appl. No.: 18/707,216

(22) PCT Filed: Nov. 7, 2022
(86) PCT No.: PCT/JP2022/041414

§ 371 Date: May 3, 2024

(30) Foreign Application Priority Data
Nov. 8, 2021 (JP) 2021-181857

(51) Int. Cl. H01S 5/14

(52) U.S. Cl. CPC H01S 5/141

(57) ABSTRACT

An optical element according to an embodiment includes a first optical member which is made of a single crystal, ceramic, or glass and to which a luminescent center excited by control light is added. A first diffraction grating that reflects light having a predetermined wavelength in a non-irradiation state where the first optical member is not irradiated with the control light or in an irradiation state where the first optical member is irradiated with the control light is formed in the first optical member, and the first diffraction grating is a volume holographic diffraction grating or a volume Bragg diffraction grating.

### TECHNICAL FIELD

The present invention relates to an optical element, an optical system, and a method for producing an optical element.

### BACKGROUND ART

Fiber Bragg diffraction grating (FBG) elements have greatly contributed to spread of fiber lasers. However, since energy that can be handled is small, a bulk volume Bragg diffraction grating (VBG) element (or a volume holographic diffraction grating (VHG) element) has attracted attention in recent years (see, for example, Patent Literature 1). The volume diffraction grating is a bulk diffraction grating. Thus, since reflection and transmission characteristics can be designed in accordance with a spectrum and an angle of light in a high energy region, the volume diffraction grating is expected to be widely used for a laser oscillation system, a non-linear optical wavelength conversion system, a light pulse decompression and compression system, and the like.

### CITATION LIST

### Patent Literature

Patent Literature 1: Japanese Unexamined Patent Publication No. 2016-224376

### SUMMARY OF INVENTION

### Technical Problem

The VBG element of the related art uses glass as a base material. Thus, for example, in a case where the VBG element is used in a laser system, there are various problems such as a stimulated emission sectional area and thermal conductivity. Further, the VBG element of the related art is a passive element, and a state of transmitting light or a state of not transmitting light depends on an initial design. That is, the VBG element of the related art is not suitable for a high-output laser material, and switching control by an external signal cannot be performed.

Therefore, an object of the present invention is to provide an optical element having a volume diffraction grating or a volume holographic diffraction grating and suitable for a high-output laser or the like, an optical system including the optical element, and a method for producing the optical element.

### Solution to Problem

An optical element according to one aspect of the present invention includes a first optical member made of a single crystal, ceramics, or glass. A first diffraction grating configured to reflect light having a predetermined wavelength is formed in the first optical member, and the first diffraction grating is a volume holographic diffraction grating or a volume Bragg diffraction grating formed by a plurality of modified regions in which a part of the first optical member is modified.

In the optical element, the first diffraction grating is formed in the first optical member made of a single crystal, ceramics, or glass. Thus, the optical element is suitable for a high-output laser or the like.

Each of the plurality of modified regions may be a planar or linear region.

A second diffraction grating constituting a resonator together with the first diffraction grating may be formed in the first optical member, and the second diffraction grating may be a volume holographic diffraction grating or a volume Bragg diffraction grating formed by a plurality of modified regions in which a part of the first optical member is modified.

The second diffraction grating is also formed in the first optical member made of a single crystal, ceramics, or glass. Thus, the optical element is suitable for a high-output laser or the like.

The resonator may be a ring resonator.

The first optical member may be a solid-state laser base material. In this case, for example, the optical element can be applied to a laser system.

The first diffraction grating may have a chirp structure. In this case, for example, pulse compression or decompression can be performed by using the optical element.

A luminescent center excited by control light may be added to the first optical member. In this case, switching control of the first optical member can be performed by the control light.

An example of an optical system according to another aspect of the present invention includes the optical element.

Another example of the optical system according to another aspect of the present invention includes the optical element, and a second optical member made of a single crystal, ceramics, or glass, a luminescent center excited by control light being added to the second optical member. A second diffraction grating forming a resonator together with the first diffraction grating configured to reflect the light having the predetermined wavelength in a non-irradiation state where the first optical member is not irradiated with the control light or an irradiation state where the first optical member is irradiated with the control light is formed in the second optical member, and the second diffraction grating is a volume holographic diffraction grating or a volume Bragg diffraction grating.

In the optical element, the first diffraction grating is formed in the first optical member made of a single crystal, ceramics, or glass. Further, the second diffraction grating forming the resonator together with the first diffraction grating of the optical element is formed in the second optical member made of a single crystal, ceramics, or glass and to which the luminescent center excited by the control light is added. Thus, the above system is suitable for a high-output laser or the like. Further, since the luminescent center excited by the control light is added to the second optical member, switching control of the second optical member in which the second diffraction grating is formed can be performed by the control light.

The resonator may be a ring resonator.

Still another example of the optical system according to another aspect of the present invention includes a plurality of optical members made of a crystal, ceramics, or glass. The plurality of optical members are disposed along one direction, a first diffraction grating configured to reflect light having a predetermined wavelength is formed in a first optical member among the plurality of optical members, and the first diffraction grating is a volume holographic diffraction grating or a volume Bragg diffraction grating formed by a plurality of modified regions in which a part of the first optical member is modified.

In the optical system, the first diffraction grating is formed in the first optical member made of a single crystal, ceramics, or glass. Thus, the above system is suitable for a high-output laser or the like.

The first optical member may be a solid-state laser base material, a heat sink, or a saturable absorber.

The first optical member may be a solid-state laser base material, a second diffraction grating constituting a resonator together with the first diffraction grating may be formed in the first optical member, and the second diffraction grating may be a volume holographic diffraction grating or a volume Bragg diffraction grating formed by a plurality of modified regions in which the first optical member is modified. In this case, the system functions as a laser system.

The first optical member may be a solid-state laser base material, a luminescent center excited by control light may be added to a second optical member among the plurality of optical members, and a second diffraction grating constituting a resonator together with the first diffraction grating may be formed in the second optical member, and the second diffraction grating may be a volume holographic diffraction grating or a volume Bragg diffraction grating. In this case, the system functions as a laser system.

An optical system according to still another aspect of the present invention is a system including a solid-state laser base material and a resonator, and configured to output a laser beam. The system includes an optical member disposed within the resonator, and made of a crystal, ceramics, or glass, a luminescent center excited by control light is added to the optical member, and a diffraction grating configured to reflect the laser beam in a direction different from an optical axis of the resonator in a non-irradiation state where the optical member is not irradiated with the control light or an irradiation state where the optical member is irradiated with the control light is formed in the optical member, and the diffraction grating is a volume holographic diffraction grating or a volume Bragg diffraction grating formed by a plurality of modified regions in which a part of the optical member is modified. In this case, the system functions as a laser system. In addition, since the diffraction grating is formed in the optical member made of a crystal, ceramics, or glass, the system is effective for a high-output laser. Further, since the luminescent center excited by the control light is added to the optical member, the optical member in which the diffraction grating is formed can be controlled by the control light.

A method for producing an optical element according to still another aspect of the present invention includes a step of forming a volume holographic diffraction grating or a volume Bragg diffraction grating configured to reflect light having a predetermined wavelength in an optical member made of a single crystal, ceramics, or glass. The volume holographic diffraction grating or the volume Bragg diffraction grating is formed by modifying the optical member by using a pulsed laser beam.

In the above method, the diffraction grating can be formed in the optical member made of a single crystal, ceramics, or glass. As a result, it is possible to produce an optical element effective for a high-output laser or the like.

A pulse width of the pulsed laser beam may be 0.1 ps to 1 ns or 1 ps to 1 ns.

The pulsed laser beam may be incident on a first surface of the optical member on which the pulsed laser beam is incident from a perpendicular direction of the first surface. Alternatively, the pulsed laser beam may be incident on a first surface of the optical member on which the pulsed laser beam is incident from an oblique direction with respect to a perpendicular direction of the first surface.

The volume holographic diffraction grating or the volume Bragg diffraction grating may be formed by a plurality of modified regions by the pulsed laser beam, and each of the plurality of modified regions may be formed in a planar or linear shape.

A first surface of the optical member on which the pulsed laser beam is incident may be a surface different from a second surface of the optical member on which the light having the predetermined wavelength is incident. Alternatively, a first surface of the optical member on which the pulsed laser beam is incident may be the same surface as a second surface of the optical member on which the light having the predetermined wavelength is incident.

### Advantageous Effects of Invention

According to the present invention, it is possible to provide the optical element having the volume diffraction grating or the volume holographic diffraction grating and suitable for the high-output laser or the like, the optical system including the optical element, and the method for producing the optical element.

### BRIEF DESCRIPTION OF DRAWINGS

FIG. 1 is a diagram illustrating a schematic configuration of an optical element according to an embodiment.

FIG. 2 is a diagram for describing a method for producing the optical element illustrated in FIG. 1.

FIG. 3 is a diagram for describing an externally controllable optical element.

FIG. 4 is a schematic diagram of an example of an optical system (laser system) according to an embodiment.

FIG. 5 is a schematic diagram illustrating a modification of the optical element used in FIG. 4.

FIG. 6 is a schematic diagram of another example of the optical system (laser system) according to an embodiment.

FIG. 7 is a schematic diagram of still another example of the optical system (laser system) according to an embodiment.

FIG. 8 is a schematic diagram of still another example of the optical system (laser system) according to an embodiment.

FIG. 9 is a schematic diagram illustrating a modification of the optical system.

FIG. 10 is a schematic diagram of still another example of the optical system (laser system) according to an embodiment.

FIG. 11 is a schematic diagram of still another example of the optical system (laser system) according to an embodiment.

FIG. 12 is a schematic diagram of still another example of the optical system (laser system) according to an embodiment.

FIG. 13 is a diagram for describing still another example of the optical element.

FIG. 14 is a diagram for describing the optical element as an optical coupling element.

FIG. 15 is a diagram for describing the optical element as a spectral filter.

FIG. 16 is a schematic diagram for describing a modification of the optical element according to an embodiment.

FIG. 17 is a schematic diagram of the optical element in FIG. 16 as viewed from a direction of light incident on the optical element.

FIG. 18 is a diagram for describing a method for producing the optical element illustrated in FIG. 16.

### DESCRIPTION OF EMBODIMENTS

Hereinafter, embodiments of the present invention will be described in detail with reference to the accompanying drawings. In the description of the drawings, the same or equivalent elements are denoted by the same reference signs, and redundant description is omitted. Dimensional ratios in the drawings do not necessarily coincide with dimensional ratios in the description. In the present disclosure, a “volume diffraction grating” is a volume holographic diffraction grating (VHG) or a volume Bragg diffraction grating (VBG).

### First Embodiment

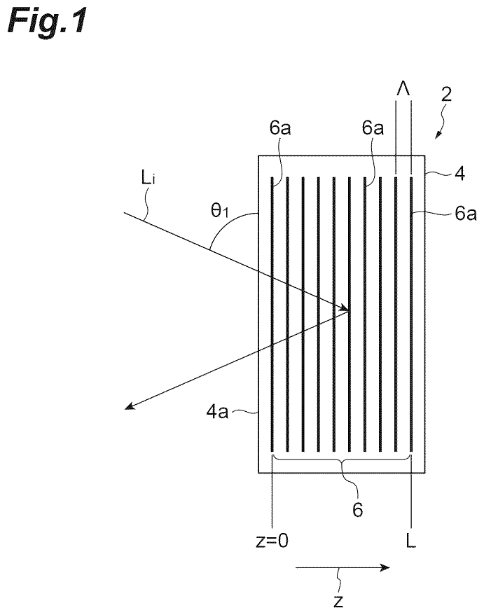

FIG. 1 is a diagram illustrating a schematic configuration of an optical element according to an embodiment. An optical element 2 illustrated in FIG. 1 includes an optical member (first optical member) 4.

The optical member 4 is a bulk crystalline body made of a single crystal, a bulk ceramic body made of ceramics, or glass. The optical member 4 has, for example, a columnar shape (including a circular columnar shape and a quadrangular prism shape).

Examples of a material of the single crystal include garnet-based materials such as YAG, GGG, LuAG, YSAG, and YGAG, oxides such as Y₂O₃, Sr₂O₃, Lu₂O₃, Al₂O₃, YALO, and Sr₂O₃, vanadate-based materials such as YVO₄, LuVO₄, and GdVO₄, fluorides such as YLF, CaF₂, and FAP, apatite-based materials, and tungstate-based materials such as WO₄. Examples of the ceramics include a polycrystal (including amorphous) of a material similar to the single crystal such as YAG ceramics. Such a single crystal and ceramics function as a solid-state laser base material.

The optical member 4 may be made of sapphire, diamond, SiC, or an additive-free laser base material. Such an optical member 4 functions as a heat sink.

The optical member 4 may be made of a non-linear optical crystal. Examples of a material of the optical member 4 made of the non-linear optical crystal include a crystal, a ferroelectric material, a semiconductor material, and a borate-based material.

Examples of the ferroelectric material include LiNbO₃ (including both a case where Mg is added and a case where Mg is not added), LiTaO₃ (including both a case where Mg is added and a case where Mg is not added), KTiPO₄ (including both a case where Rb is added and a case where Rb is not added), RbTiPO₄ (including both a case where Rb is added and a case where Rb is not added), KTiOAsO₄, and RbTiOAsO₄.

Examples of the semiconductor material include GaAs, GaP, GaN, ZnS, ZnSe, ZnTe, ZnGeP₂, and CdSiP₂.

Examples of the borate-based material include LiB₃O₅, BaB₂O₄, Ca(BO₃)₃F, CsLiB₆O₁₀, and Ca₄LnO(BO₃)₃(Ln=Gd,Y).

In the optical member 4, a volume diffraction grating (first diffraction grating) 6 that selectively reflects light having a predetermined wavelength is formed. The volume diffraction grating 6 is VHG or VBG. The volume diffraction grating 6 has a plurality of modified surfaces (modified regions) 6a disposed with a period A. The modified surfaces 6a are surfaces obtained by modifying the optical member 4 and are refractive index modulated surfaces having a refractive index different from a refractive index of a region other than the modified surface 6a. In one embodiment, each modified surface 6a may be a region where a plurality of modified portions are formed in a planar shape. In FIG. 1, for the sake of convenience in description, the modified surfaces 6a are schematically illustrated by thick solid lines. The modified surfaces 6a are illustrated similarly in other drawings.

The optical element 2 can be produced by forming the volume diffraction grating 6 in the optical member 4. That is, a method for producing the optical element 2 includes a step of forming the volume diffraction grating 6 in the optical member 4.

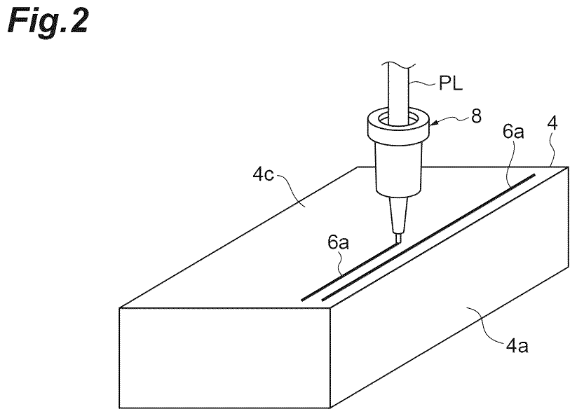

The volume diffraction grating 6 can be formed by laser drawing. Specifically, as illustrated in FIG. 2, a pulsed laser beam PL is condensed by a condensing unit 8, and the optical member 4 in an irradiation region of the pulsed laser beam PL is modified. In a case where the optical element 2 is formed, the pulsed laser beam PL is incident from a surface (first surface) 4c of the optical member 4. The surface 4c is a surface different from an end surface (second surface) 4a on which light Lᵢ is incident in a case where the light Lᵢ is incident on the optical element 2 in which the volume diffraction grating 6 is formed as illustrated in FIG. 1. In the example illustrated in FIG. 2, the surface 4c is a surface substantially orthogonal to the end surface 4a. The plurality of modified surfaces 6a are formed by three-dimensionally scanning the pulsed laser beam PL in accordance with a size and period A of the volume diffraction grating 6 to be formed. As a result, the volume diffraction grating 6 is written in the optical member 4, and the optical element 2 is obtained. The pulsed laser beam PL can function as a writing laser beam for writing the modified surface 6a. In a case where a portion modified in the irradiation region is referred to as a modified portion, each modified surface 6a is formed by disposing the plurality of modified portions in the planar shape. In the example illustrated in FIG. 2, the pulsed laser beam PL is incident in a direction perpendicular to the surface 4c. However, the pulsed laser beam PL may be incident on the surface 4c from an oblique direction (a direction inclined from the perpendicular direction).

The pulsed laser beam PL may be a pulsed laser beam having a pulse width of sub-picosecond to nanosecond. The pulse width of the pulsed laser beam PL may be 0.1 ps to 10 ns. The pulse width may be 0.1 ps to 1 ns or 1 ps to 1 ns. An example of a laser system 10 that outputs the pulsed laser beam PL is a micro chip laser (MCL) (see, for example, Japanese Unexamined Patent Publication No. 2019-129252) that is small in size, low in power consumption, and capable of outputting a laser beam having a pulse width of sub-nanosecond. An example of a wavelength in a case where the optical member 4 is Nd:YAG and the pulsed laser beam PL is a fundamental wave is 1064 nm. An example of a wavelength in a case where the optical member 4 is Yb:YAG and the pulsed laser beam PL is a fundamental wave is 1024 nm to 1108 nm. Not only the fundamental wave but also harmonics such as a second harmonic wave, a third harmonic wave, a fourth harmonic wave, a fifth harmonic wave, a sixth harmonic wave, and a seventh harmonic wave from the solid-state laser may be used as the pulsed laser beam PL. Harmonics are used, and thus, photon energy can be increased without using a large and unstable ultrashort pulse laser with a pulse width of less than 0.1 ps. Thus, the pulsed laser beam PL efficiently strongly interacts with a substance, and finer machining can be performed.

A power, an irradiation time, and the like of the pulsed laser beam PL may be set such that a refractive index at an irradiation position (condensing position) of the pulsed laser beam PL can be modulated to a refractive index capable of functioning as the volume diffraction grating 6. For example, an example of a peak output of the pulsed laser beam PL is 0.1 MW to 50 MW. The irradiation time at the irradiation position of the pulsed laser beam PL is 0.1 ps to 1 ns.

In the scanning of the pulsed laser beam PL, the laser system itself that outputs the pulsed laser beam PL may be scanned, or the pulsed laser beam PL output from the laser system 10 may be scanned by using a mirror or the like.

As illustrated in FIG. 1, it is assumed that the volume diffraction grating 6 includes the plurality of modified surfaces 6a disposed in parallel with the period A. A direction in which the plurality of modified surfaces 6a are arrayed (a direction orthogonal to the modified surfaces 6a) is referred to as a z direction, one end in the z direction in a region where the volume diffraction grating 6 is formed is z=0, and a width of the volume diffraction grating 6 in the z direction is L. It is assumed that light Lᵢ having a predetermined wavelength 2 is incident on the optical member 4.

In this case, a refractive index distribution n (z) of the volume diffraction grating 6 in the z direction, the period ∧ (Bragg reflection condition) with which diffraction efficiency is maximized with the light Lᵢ, and a maximum reflectance R are expressed by Formulae (1), (2), and (3) (see, for example, Reference Literature 1 below). Formula (3) corresponds to a phase matching condition. In Formulae (1) to (3), n₀ is a refractive index (refractive index before modification) other than the modified surface 6a in the optical member 4, n₁ is a refractive index of the modified surface 6a, and θ₁ is an angle formed between an incident direction of the light Lᵢ on the volume diffraction grating 6 and the volume diffraction grating 6 (specifically, the modified surface 6a).

Reference Literature 1: P. Yen, “Photorefractive Non-linear Optics”, Maruzen GROUP, Mar. 1, 1995, p. 53 to p. 73.

$$[ Formula 1 ]$$

$$n ( z ) = {n}_{0} + {n}_{1} sin ( 2 π z / Λ ) \qquad ( 1 )$$

$$[ Formula 2 ]$$

$$Λ = \frac{λ}{2 {n}_{0} sin {θ}_{1}} \qquad ( 2 )$$

$$[ Formula 3 ]$$

$$R = {tanh}^{2} ( \frac{π {n}_{1} L}{λ sin {θ}_{1}} ) = {tanh}^{2} ( \frac{2 π {n}_{1} {n}_{0} Λ L}{{λ}^{2}} ) \qquad ( 3 )$$

In Formula (2), ∧ is λ/(2n₀) in a case where θ₁=π/2.

According to, for example, page 42 of Reference Literature 1, when 10⁻³ to 10⁻⁵ can be secured as n₁ in Formulae (1) to (3), the volume diffraction grating 6 effectively functions.

In the optical element 2, the volume diffraction grating (first diffraction grating) 6 that selectively reflects light having a predetermined wavelength is formed. Thus, light having a predetermined wavelength of incident light is reflected, and light having a wavelength deviated from the predetermined wavelength is transmitted. As described in the above production method, the optical element 2 is formed by modifying a part of the optical member 4 by using, for example, a laser beam. The optical member 4 is a bulk crystalline body made of a single crystal or a bulk ceramic body made of ceramics. As described above, in the above production method, the diffraction grating can be formed on a single crystal, a ceramic body, or the like.

Thus, the above production method is used, and thus, it is possible to form a diffraction grating in a single crystal for a solid-state laser, a ceramic body, or the like, which has not been realized in the related art. As a result, for example, a resonator can be directly formed in a single crystal for a solid-state laser, a ceramic body, or the like, and an oscillation wavelength can be locked. At a bonding interface with a different material, it is necessary to perform partial reflection coating depending on a situation, but there is a disadvantage that the partial reflection coating is mechanically brittle due to vapor deposition of a multilayer film. In the above production method, since a fragile multilayer film is not required, a stronger composite element can be realized.

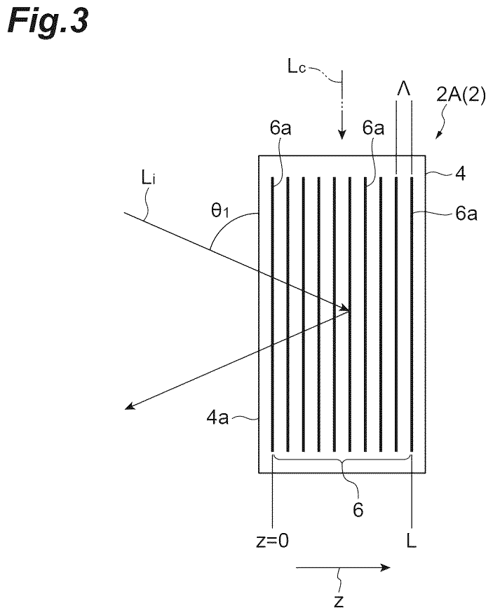

In a case where the single crystal, the ceramic body, or the like is made of a solid-state laser material, since various luminescent centers can be added, external control based on excitation thereof can also be realized. This point will be described. FIG. 3 is a diagram for describing an externally controllable optical element.

As illustrated in FIG. 3, the optical element 2 in a case where a luminescent center is added to the optical member is referred to as an optical element 2A. In the optical element 2A, the luminescent center (first luminescent center) excited by control light L_{C} (external signal) having a control wavelength λ_{C} is added to an optical member. Examples of the luminescent center include rare earth elements (Nd, Yb, Tm, Ho, Er, Ce, Pr, Dy, Tb, Sm, and the like) and transition metal elements (Cr, Ti, V, and the like).

As illustrated in FIG. 3, in a case where the control light L_{C} having the control wavelength λ_{C} is incident on the optical element 2, the luminescent center (for example, RE³⁺ or the like) is excited, and refractive index modulation Δn is generated. The maximum reflectance R in consideration of the refractive index modulation Δn is expressed by Formula (4).

$$[ Formula 4 ]$$

$$R = {tanh}^{2} ( \frac{2 π ( {n}_{1} + Δ n ) ( {n}_{0} + Δ n ) ΛL}{{λ}^{2}} ) \qquad ( 4 )$$

Since n₀ is usually sufficiently larger than Δn, Formula (4) can be approximated as Formula (5).

$$[ Formula 5 ]$$

$$R = {tanh}^{2} ( \frac{2 π ( {n}_{1} + Δ n ) {n}_{0} Λ L}{{λ}^{2}} ) \qquad ( 5 )$$

The refractive index modulation Δn is divided into a change (Δnₑ) due to electronic transition and a change (Δn_{T}) due to heat generation. That is, Δn is expressed by Formula (6).

$$[ Formula 6 ]$$

$$Δ n = Δ {n}_{e} + Δ {n}_{T} \qquad ( 6 )$$

Here, Δnₑ and Δn_{T} are expressed by Formulae (7) and (8).

$$[ Formula 7 ]$$

$$Δ {n}_{e} = \frac{2 π {F}_{L}^{2} Δ p Δ N}{{n}_{0}} \qquad ( 7 )$$

$$[ Formula 8 ]$$

$$Δ {n}_{T} = ( \frac{\partial n}{\partial T} ) Δ T \qquad ( 8 )$$

In Formula (7), ΔN is an inversion distribution density. F_{L} is a Lorents factor and is expressed by (n₀+2)/3. Δp is polarizability between a ground level and an excited level. The following numerical values are adopted as Δp and (∂n/∂T) (see, for example, Reference Literature 2 below).

$$Δ p = ( 1.95 \pm 0.25 ) \times 1 {0}^{- 26} [ {cm}^{3} ]$$

$$\partial n / \partial T \approx ( 0.7 \pm 0.2 ) \times 1 {0}^{- 5}$$

Reference Literature 2: O. L. Antipov, D. V. Bredikhin, O. N. Eremeykin, A. P. Savikin, E. V. Ivakin, and A. V. Sukhadolau, “Electronic mechanism for refractive-index changes in intensively pumped Yb:YAG laser crystals,” OPTICS LETTERS, 2006, Vol. 31, No. 6, 763-765.

In this case, for example, when the optical element 2A is formed at Yb:YAG (addition amount of Yb: 100 at. %) and is excited by 100%, a refractive index change of Δnₑ up to about 2.93×10⁻³ occurs. Even though the addition amount of Yb is 0.68 at. %, a refractive index change of about 10⁻⁵ occurs by exciting the optical member by 50%. Thus, the optical element 2A is irradiated with the control light L_{C} to excite the luminescent center, and thus, it is possible to secure, as Δn, a refractive index change in the case of functioning as the volume diffraction grating 6 described above. In other words, the optical element 2A is irradiated with the control light L_{C} to excite the luminescent center, and thus, it is possible to secure, as Δn, the refractive index change that affects reflection characteristics of the volume diffraction grating 6.

Accordingly, in a case where the volume diffraction grating 6 is designed to reflect the light Lᵢ in a state (non-irradiation state) where the optical element 2A is not irradiated with the control light L_{C}, and when the optical element 2A is irradiated with the control light L_{C}, the condition (phase matching condition) expressed by Formula (3) is not satisfied. As a result, the light Lᵢ having the predetermined wavelength λ is not reflected by the volume diffraction grating 6.

Conversely, in a case where the volume diffraction grating 6 is designed to reflect the light Lᵢ in a state (irradiation state) where the optical element 2A is irradiated with the control light L_{C}, the condition (phase matching condition) expressed by Formula (3) is not satisfied in the non-irradiation state where the irradiation of the control light L_{C} is stopped. As a result, the light Lᵢ having the predetermined wavelength λ is not reflected by the volume diffraction grating 6.

Thus, the optical element 2A can be switched between a case where the optical element 2A (specifically, the volume diffraction grating 6) reflects the light Lᵢ and a case where the optical element does not reflect the light Lᵢ (that is, transmits the light) depending on whether or not the optical element 2A is irradiated with the control light L_{C} (in other words, switching between the irradiation state and the non-irradiation state). Accordingly, the optical element 2A functions as a switch element capable of externally controlling reflection characteristics.

Since the function of the optical element 2A can be switching-controlled depending on whether or not the optical element is irradiated with the control light L_{C}, a switching speed can be improved in the optical element 2A, and the optical element 2A can be controlled with high accuracy using a picosecond pulse or a femtosecond pulse.

The optical elements 2 and 2A can be applied to a laser machining system, a laser measurement system, a laser medical system, and other optical systems (including physicochemical systems) in accordance with the material of the optical member 4 and the functions of the optical elements 2 and 2A according to the design of the volume diffraction grating 6.

In a case where the optical member 4 is made of a single crystal or ceramics, the optical member 4 has high resistance to the power of the incident light. Thus, the optical elements 2 and 2A can be used as switch elements for a high-output laser beam, and can be applied to, for example, a laser system that outputs (or handles) high-output laser beam (for example, pulsed laser beam), a laser machining system, a non-linear wavelength conversion system, a light pulse decompression or compression system, and the like.

Next, embodiments of various systems or apparatuses using the optical element 2 or the optical element 2A will be described. In embodiments to be described below, a solid-state laser base material, a heat sink, a non-linear crystal, and the like are the optical member 4.

### Second Embodiment

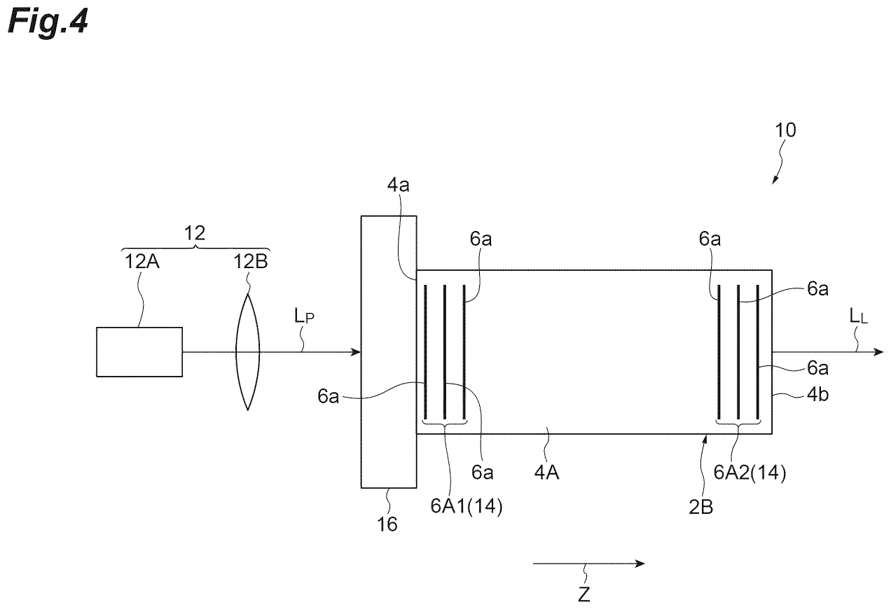

As a second embodiment, an optical system including the optical element according to the present disclosure will be described. FIG. 4 is a schematic diagram of a laser system 10 which is an example of the optical system including the optical element. The laser system (optical system) 10 illustrated in FIG. 4 is a system that outputs a laser beam L_{L}, having a laser wavelength λ_{L}.

The laser system 10 includes a first light supply unit (excitation light supply unit) 12 and an optical element 2B.

The first light supply unit 12 supplies excitation light L_{P} having an excitation wavelength 2 to the optical element 2B. The first light supply unit 12 includes a light source unit 12A that outputs the excitation light L_{P} and a condensing optical system 12B that condenses the excitation light L_{P} to be incident on the optical element 2B. FIG. 4 schematically illustrates the condensing optical system 12B as a lens. An example of the light source unit 12A is a semiconductor laser element.

The excitation light L_{P} is supplied, and thus, the optical element 2B functions as an optical oscillator (or an optical amplifier) that outputs the laser beam L_{L}. The optical element 2B includes an optical member 4A. A volume diffraction grating 6A1 and a volume diffraction grating (second diffraction grating) 6A2 are formed in the optical member 4A. The volume diffraction grating 6A1 and the volume diffraction grating 6A2 constitute a resonator 14.

The optical member 4A has an end surface 4a and an end surface 4b. The end surface 4b is an end surface opposite to the end surface 4a. Unless otherwise noted, the end surface 4a and the end surface 4b are parallel. For the sake of convenience in description, a direction orthogonal to the end surface 4a (or the end surface 4b) may be referred to as a Z direction. In the second embodiment, the Z direction corresponds to an optical axis direction of the resonator 14.

The optical member 4A is made of a solid-state laser base material to which a luminescent center (second luminescent center) excited by the excitation light L_{P} having the excitation wavelength λ_{P} is added. That is, the optical member 4A is a laser medium. The optical member 4A has, for example, a columnar shape (including a circular columnar shape and a quadrangular prism shape).

An example of the luminescent center added to the optical member 4A is a rare earth or a transition metal similar to the example of the luminescent center described for the optical element 2 in the first embodiment. An example of the solid-state laser base material forming the optical member 4A is similar to the case of the optical member 4. The optical member 4A is formed from, for example, YAG (Nd:YAG) to which Nd is added.

The volume diffraction grating 6A1 is formed on the end surface 4a side in the optical member 4A, and functions as an input-side reflection unit (first reflection unit) in the resonator 14. The volume diffraction grating 6A1 has, as the input-side reflection unit of the resonator 14, transmission characteristics with respect to the excitation light L_{P} and reflection characteristics with respect to the laser beam L_{L}.

In one embodiment, the volume diffraction grating 6A1 has a transmittance of larger than 80% (preferably larger than 90%) for the excitation wavelength λ_{P} (wavelength 808 nm, wavelength 885 nm, or the like) and has a reflectance of larger than 99% for the laser wavelength (laser oscillator wavelength) 2. (for example, wavelength 1064 nm).

The volume diffraction grating 6A1 has a plurality of modified surfaces 6a formed in the optical member 4A. The volume diffraction grating 6A1 can be formed by laser drawing similarly to the case of the volume diffraction grating 6 in the first embodiment. The disposition (for example, period) of the plurality of modified surfaces 6a of the volume diffraction grating 6A1 and a refractive index of the modified surface 6a may be set to realize the transmission characteristics and the reflection characteristics corresponding to the input-side reflection unit of the resonator 14. That is, the volume diffraction grating 6A1 corresponds to the volume diffraction grating 6 designed to function as the input-side reflection unit of the resonator 14.

The volume diffraction grating 6A2 is formed on the end surface 4b side in the optical member 4A, and functions as an output-side reflection unit (second reflection unit) in the resonator 14. The volume diffraction grating 6A2 has, as the output-side reflection unit of the resonator 14, transmission characteristics with respect to the excitation light L_{P} and reflection characteristics with respect to the laser beam L_{L}.

In one embodiment, the volume diffraction grating 6A2 has a reflectance (partial reflectance) of 90% to 99% for output coupling with respect to the laser wavelength λ_{L}. (for example, wavelength 1064 nm) that is the laser oscillation wavelength. The volume diffraction grating 6A2 may not reflect the light having the excitation wavelength λ_{P}. However, the volume diffraction grating 6A2 has a reflectance larger than 50% with respect to the excitation wavelength λₚ, and thus, a medium length (specifically, a length between the volume diffraction grating 6A1 and the volume diffraction grating 6A2 in the optical member 4A) can be shortened. Accordingly, stable and efficient laser oscillation, in particular, CW laser oscillation can be performed.

The volume diffraction grating 6A2 has a plurality of modified surfaces 6a formed in the optical member 4A. The volume diffraction grating 6A2 can be formed by laser drawing similarly to the case of the volume diffraction grating 6 in the first embodiment. The disposition (for example, period) of the plurality of modified surfaces 6a of the volume diffraction grating 6A2 and a refractive index of the modified surface 6a may be set to realize the transmission characteristics and the reflection characteristics corresponding to the output-side reflection unit of the resonator 14. That is, the volume diffraction grating 6A2 corresponds to the volume diffraction grating 6 designed to function as the output-side reflection unit of the resonator 14.

The laser system 10 may have a heat sink 16 on the end surface 4a side. The heat sink 16 is bonded to the optical member 4A. Examples of a material of the heat sink 16 include sapphire and diamond. The heat sink 16 and the optical element 2B (specifically, the optical member 4A) may be bonded by a known bonding method. For example, the heat sink 16 is integrated with the optical element 2B (specifically, the optical member 4A) by an adhesive, an optical contact, or surface-active low-temperature bonding (hereinafter, also simply referred to as “surface-active coupling”).

The surface-active coupling is a technique in which an oxide film or a surface deposit on a bonding surface of a material to be bonded in vacuum is removed by ion beam irradiation or FAB (neutral atomic beam) irradiation, and bonding surfaces that are flat and have exposed constituent atoms are bonded to each other. The surface-active coupling is direct bonding using intermolecular coupling.

In the laser system 10, the volume diffraction grating 6A1 and the volume diffraction grating 6A2 are formed in the optical member 4A made of the solid-state laser base material to which the luminescent center is added. Accordingly, the optical element 2B corresponds to the optical element 2 in the first embodiment, and the optical element 2B has functions and effects similar to the optical element 2. For example, since the volume diffraction grating 6A1 and the volume diffraction grating 6A2 are formed in the optical member 4A, mechanical strength of the optical element 2B as the optical oscillator is improved as compared with a case where a dielectric multilayer film is used.

In the laser system 10, the volume diffraction grating 6A1 and the volume diffraction grating 6A2 constitute the resonator 14. That is, the resonator 14 is formed in the optical member 4A. Accordingly, the laser beam L_{L}, can be generated by causing the excitation light L_{P} to be incident on the optical element 2B.

A dielectric multilayer film may be used instead of one of the volume diffraction grating 6A1 and the volume diffraction grating 6A2. Even in this case, the mechanical strength of the optical element 2B as the optical oscillator is improved as compared with a case where two reflection units constituting the resonator 14 are both made of the dielectric multilayer film.

### (Modification 1)

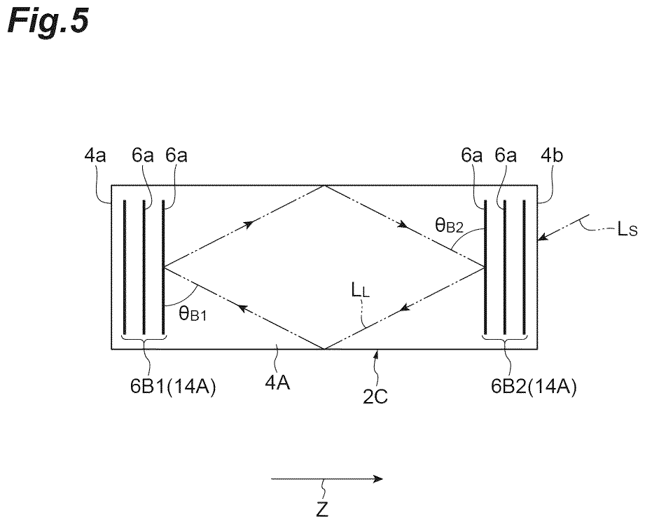

An optical element 2C which is a modification of the optical element 2B will be described with reference to FIG. 5. FIG. 5 is a diagram for describing a modification of the optical element illustrated in FIG. 4. The optical element 2C includes an optical member 4A, a volume diffraction grating 6B1, and a volume diffraction grating 6B2. The optical element 2C is mainly different from the optical element 2B in that the optical element 2C includes the volume diffraction grating 6B1 and the volume diffraction grating 6B2 instead of the volume diffraction grating 6A1 and the volume diffraction grating 6A2 and the volume diffraction grating 6B1 and the volume diffraction grating 6B2 constitute a ring resonator 14A.

Since the optical member 4A in Modification 1 is the same as the optical member 4A illustrated in FIG. 4, the description thereof is omitted.

The volume diffraction grating 6B1 is similar to the volume diffraction grating 6A1 except that the volume diffraction grating 6B1 is designed to reflect a laser beam L_{L} incident at a blaze angle θ_{B1}. That is, the volume diffraction grating 6B1 is disposed on an end surface 4a side and has a plurality of modified surfaces 6a manufactured similarly to the case of the volume diffraction grating 6A1. The volume diffraction grating 6B1 functions as an input-side reflection unit in the ring resonator 14A.

The volume diffraction grating 6B2 is similar to the volume diffraction grating 6A2 except that the volume diffraction grating 6B2 is designed to reflect laser beam L_{L} incident at a blaze angle θ_{B2}. That is, the volume diffraction grating 6B2 is disposed on an end surface 4b side, and has a plurality of modified surfaces 6a manufactured similarly to the case of the volume diffraction grating 6A2. The volume diffraction grating 6B2 functions as an output-side reflection unit in the ring resonator 14A.

With the above configuration, the ring resonator 14A including the volume diffraction grating 6B1 and the volume diffraction grating 6B2 is a resonator in which the laser beam L_{L} propagates in a ring shape at the blase angle θ_{B1} and the blase angle θ_{B2} with respect to the laser beam L_{L}.

The optical element 2C is the optical member 4A in which the volume diffraction grating 6B1 and the volume diffraction grating 6B1 are formed. Thus, the optical element 2C corresponds to the optical element 2 in the first embodiment, and the optical element 2C has functions and effects similar to the optical element 2.

The optical element 2C can be applied to the laser system 10 instead of the optical element 2B.

The optical element 2C includes the ring resonator 14A, and thus, it is possible to secure a resonator length while reducing a size of the optical element 2C.

In a case where the optical element 2C of Modification 1 is applied to the laser system 10, the laser system 10 may further include an external magnetic field supply unit that applies an external magnetic field to the optical element 2C along the Z direction. As a result, it is possible to use a Faraday effect. As illustrated in FIG. 5, seed light L_{S} may be incident from an outside of the optical element 2C. In a case where the seed light Ls is incident on the optical element 2C as described above, since the laser system including the ring resonator (optical element 2C) can perform light injection synchronization with the laser beam, an oscillation wavelength and a phase thereof can be controlled.

### Third Embodiment

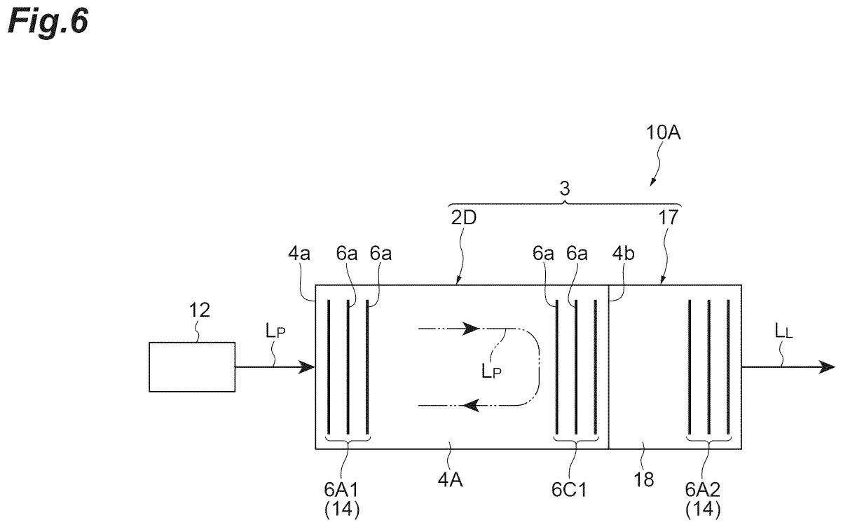

As a third embodiment, another example of the optical system including the optical element according to the present disclosure will be described. FIG. 6 is a schematic diagram of a laser system 10A which is an example of the optical system including the optical element. The laser system 10A illustrated in FIG. 6 is a system that outputs a pulsed laser beam as the laser beam L_{L} having the laser wavelength λ_{L}.

The laser system 10A is a passive Q-switch laser system including a first light supply unit 12, an optical element 2D, and a saturable absorption unit 17. As will be described later, in the laser system 10A, a resonator 14 is formed by a volume diffraction grating 6A1 of the optical element 2D and a volume diffraction grating 6A2 of the saturable absorption unit 17.

The first light supply unit 12 supplies excitation light L_{P} to the optical element 2D. Since a configuration of the first light supply unit 12 is similar to the case of the second embodiment, the description thereof is omitted. In FIG. 6, the first light supply unit 12 is schematically illustrated as a block.

The optical element 2D is mainly different from the optical element 2B in that the optical element 2D includes a volume diffraction grating 6C1 instead of the volume diffraction grating 6A2. The optical element 2D includes an optical member 4A, the volume diffraction grating 6A1, and the volume diffraction grating 6C1.

Since the optical member 4A is similar to the case of the second embodiment, the description thereof is omitted. A configuration and a production method of the volume diffraction grating 6A1 are similar to the case of the second embodiment. In the third embodiment, the volume diffraction grating 6A1 also functions as the incident-side reflection unit in the resonator 14.

The volume diffraction grating 6C1 has a plurality of modified surfaces 6a. The volume diffraction grating 6C1 has a reflectance (preferably, reflectance greater than 90%) greater than 50% with respect to excitation light L_{P} having an excitation wavelength λ_{P}. A production method of the volume diffraction grating 6C1 is similar to the case of the volume diffraction grating 6 in the first embodiment.

The saturable absorption unit 17 is bonded to an end surface 4b of the optical member 4A. The saturable absorption unit 17 includes a saturable absorber 18 and the volume diffraction grating 6A2.

An example of the saturable absorber 18 is a Q-switch element. The saturable absorber 18 corresponds to the optical member 4 configured to have saturable absorption characteristics, and the saturable absorber 18 may be formed at YAG (Cr: YAG) to which Cr is added. The saturable absorber 18 is bonded to the end surface 4b of the optical member 4A. The saturable absorber 18 is integrated with the optical element 2D (specifically, the optical member 4A) by, for example, an adhesive, an optical contact, or surface-active bonding. Hereinafter, for the sake of convenience in description, the bonded body of the optical element 2D and the saturable absorption unit 17 is referred to as an optical element 3.

The volume diffraction grating 6A2 constituting the resonator 14 together with the volume diffraction grating 6A1 is formed on an end surface (surface opposite to the optical element 2D) side of the saturable absorber 18. The volume diffraction grating 6A2 has a plurality of modified surfaces 6a, and reflection characteristics and transmission characteristics of the volume diffraction grating 6A2 are similar to the case of the second embodiment. A production method of the volume diffraction grating 6A2 is similar to the case of the volume diffraction grating 6 in the first embodiment.

In the laser system 10A, the volume diffraction grating 6A1 and the volume diffraction grating 6A2 also constitute the resonator 14. The laser system 10A includes the saturable absorber 18. Thus, the pulsed laser beam can be output as the laser beam L_{L}.

In the third embodiment, the optical element 2D corresponds to the optical element 2. The saturable absorption unit 17 also corresponds to the optical element 2. Thus, the optical element 2D and the saturable absorption unit 17 (optical element) have functions and effects similar to the optical element 2.

In the laser system 10A, the volume diffraction grating 6C1 having high reflectance with respect to the excitation light L_{P} having the excitation wavelength λ_{P} is formed in the optical member 4A. For example, when realizing similar reflection characteristics by something other than the volume diffraction grating 6C1, it would be conceivable to form a dielectric multilayer film having reflection characteristics similar to the volume diffraction grating 6C1 between the optical member 4A and the saturable absorber 18. However, since such a dielectric multilayer film has low mechanical strength, there is a case where the dielectric multilayer film is damaged when the optical member 4A and the saturable absorber 18 are bonded via the dielectric multilayer film. Even after the optical member 4A and the saturable absorber 18 are integrated with each other via the dielectric multilayer film, there is weakness in terms of strength. On the other hand, in the laser system 10A, since the volume diffraction grating 6C1 is formed in the optical member 4A, the above-described damage at the time of manufacture does not occur, and there is no weakness after manufacture. In particular, in a case where the optical member 4A (for example, Nd:YAG) and the saturable absorber 18 (for example, Cr: YAG) are bonded by surface-active coupling, since strong bonding at an atomic level is expected, the optical element 3 can have resistance to an external pressure.

In the laser system 10A, the volume diffraction grating 6A1 is formed in the optical member 4A, and the volume diffraction grating 6A2 is formed in the saturable absorber 18. Thus, the optical element 3 can have higher resistance to an external pressure.

In the laser system 10A, the volume diffraction grating 6C1 may be formed in the saturable absorber 18. In the laser system 10A, a dielectric multilayer film formed on an end surface 4a of the optical member 4A may be used as the input-side reflection unit instead of the volume diffraction grating 6A1. In the laser system 10A, instead of the volume diffraction grating 6A2, a dielectric multilayer film formed on the end surface (end surface opposite to the optical element 2D) of the saturable absorber 18 may be used as an output-side reflection unit.

### Fourth Embodiment

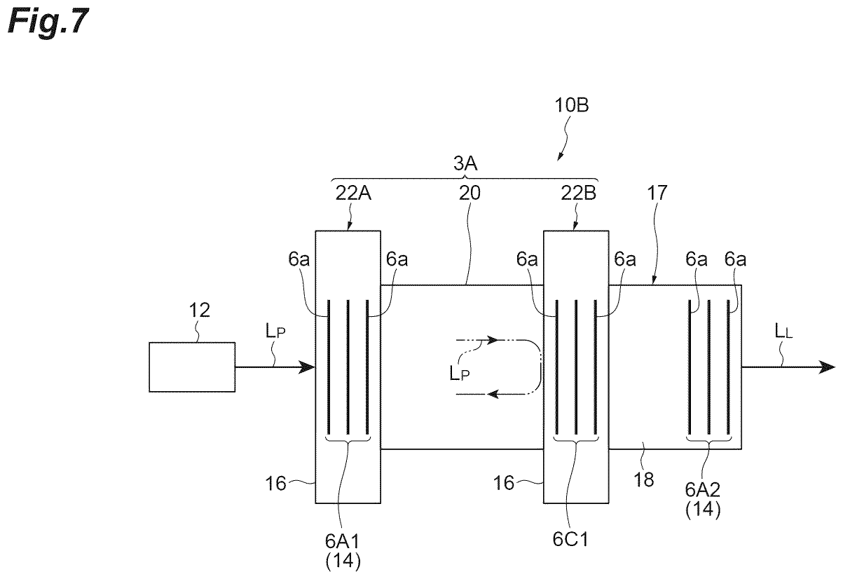

As a fourth embodiment, another example of the optical system including the optical element according to the present disclosure will be described. FIG. 7 is a schematic diagram of a laser system 10B which is an example of the optical system including the optical element. The laser system 10B illustrated in FIG. 7 is a system that outputs a pulsed laser beam as a laser beam L_{L} having a laser wavelength λ_{L}.

The laser system 10B includes a first light supply unit (excitation light supply unit) 12, a laser medium 20, a heat dissipation unit 22A, a heat dissipation unit 22B, and a saturable absorption unit 17. As will be described later, in the laser system 10B, a resonator 14 is formed by a volume diffraction grating 6A1 of the heat dissipation unit 22A and a volume diffraction grating 6A2 of the saturable absorption unit 17.

The first light supply unit 12 supplies excitation light L_{P} to the laser medium 20. Since a configuration of the first light supply unit 12 is similar to the case of the second embodiment, the description thereof is omitted. The laser medium 20 can be similar to the optical member 4A in the third embodiment. The laser medium 20 is formed at, for example, Nd:YAG. Since the saturable absorption unit 17 is also similar to the case of the third embodiment, the description thereof is omitted.

The heat dissipation unit 22A includes a heat sink 16 and a volume diffraction grating 6A1. In other words, the heat dissipation unit 22A is the heat sink 16 in which the volume diffraction grating 6A1 is formed. The heat sink 16 is also an example of the optical member 4. The volume diffraction grating 6A1 can have a configuration and optical characteristics (reflection characteristics and transmission characteristics) similar to the case of the first embodiment. A production method of the volume diffraction grating 6A1 is also similar to the case of the first embodiment. The heat dissipation unit 22A (specifically, the heat sink 16) is integrated with the laser medium 20 by an adhesive, an optical contact, or surface-active bonding.

The heat dissipation unit 22B has a heat sink 16 and a volume diffraction grating 6C1. In other words, the heat dissipation unit 22B is the heat sink 16 in which the volume diffraction grating 6C1 is formed. The heat dissipation unit 22B can have a configuration similar to the heat dissipation unit 22A except that the volume diffraction grating 6C1 is formed instead of the volume diffraction grating 6A1. The volume diffraction grating 6C1 can have a configuration and optical characteristics (reflection characteristics and transmission characteristics) similar to the case of the third embodiment. A production method of the volume diffraction grating 6C1 is also similar to the case of the third embodiment. The heat dissipation unit 22B (specifically, the heat sink 16) is integrated with the laser medium 20 and the saturable absorption unit 17 (specifically, the saturable absorber 18) by an adhesive, an optical contact, or surface-active bonding.

In the fourth embodiment, each of the heat dissipation unit 22A, the heat dissipation unit 22B, and the saturable absorption unit 17 corresponds to the optical element 2. Thus, the heat dissipation unit 22A, the heat dissipation unit 22B, and the saturable absorption unit 17 as the optical elements have functions and effects similar to the optical element 2.

For the sake of convenience in the following description, a stacked body formed by the heat dissipation unit 22A, the laser medium 20, the heat dissipation unit 22B, and the saturable absorption unit 17 is referred to as an optical element 3A.

In the laser system 10B, the volume diffraction grating 6A1 and the volume diffraction grating 6A2 constitute the resonator 14. The laser system 10B has the saturable absorber 18. Thus, the laser system 10B can output a pulsed laser beam as the laser beam L_{L}.

In the laser system 10B, the heat dissipation unit 22B is disposed between the laser medium 20 and the saturable absorption unit 17. In the laser system 10B, the volume diffraction grating 6C1 is formed in the heat sink 16 of the heat dissipation unit 22B. Thus, similarly to the case of the laser system 10A, for example, the mechanical strength of the optical element 3A is improved as compared with a case where reflection characteristics similar to the volume diffraction grating 6C1 are realized by a dielectric multilayer film.

From a similar viewpoint, since the volume diffraction grating 6A1 is also formed in the heat sink 16, the mechanical strength of the optical element 3A is improved. Further, since the volume diffraction grating 6A2 is formed in the saturable absorber 18, the mechanical strength of the optical element 3A is improved.

In the laser system 10B, instead of the volume diffraction grating 6A2, a dielectric multilayer film formed on an end surface of the saturable absorber 18 (end surface on the opposite side of the heat dissipation unit 22B) may be used as an output-side reflection unit.

### Fifth Embodiment

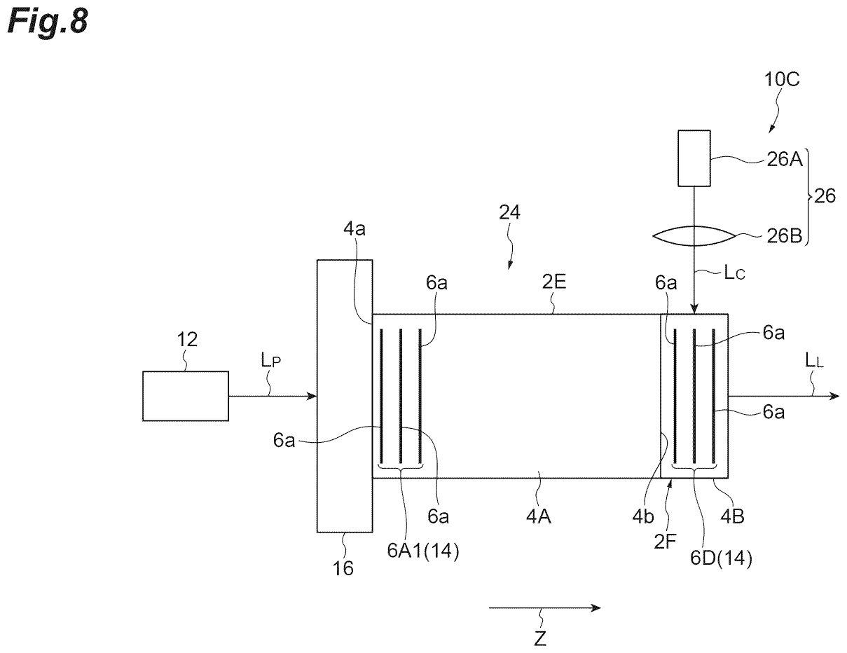

As a fifth embodiment, the optical system including the optical element according to the present disclosure will be described. FIG. 8 is a schematic diagram of a laser system 10C which is an example of the optical system including the optical element. The laser system 10C illustrated in FIG. 8 is a system that outputs a laser beam L_{L} having a laser wavelength λ_{L}.

The laser system 10C includes a first light supply unit 12, an optical oscillator 24, and a second light supply unit (control light supply unit) 26.

The first light supply unit 12 supplies excitation light L_{P} to the optical oscillator 24. Since a configuration of the first light supply unit 12 is similar to the case of the second embodiment, the description thereof is omitted.

The optical oscillator 24 includes an optical element 2E and an optical element 2F. A volume diffraction grating 6A1 of the optical element 2E and a volume diffraction grating 6D of the optical element 2F form a resonator 14. The excitation light L_{P} is supplied, and thus, the optical oscillator 24 outputs laser beam L_{L}. The optical oscillator 24 may have a heat sink 16. In the fifth embodiment, the optical oscillator 24 including the heat sink 16 will be described.

As illustrated in FIG. 8, the heat sink 16, the optical element 2E, and the optical element 2F are disposed in this order along the Z direction.

The optical element 2E is different from the optical element 2B in the second embodiment in that the volume diffraction grating 6A2 is not formed. That is, the optical element 2E is an optical member 4A in which the volume diffraction grating 6A1 is formed. Since the optical member 4A and the volume diffraction grating 6A1 are the same as the case of the second embodiment, the description thereof is omitted.

The optical element 2F includes an optical member (second optical member) 4B and a volume diffraction grating (second diffraction grating) 6D. The optical element 2F is an optical member 4B in which the volume diffraction grating 6D is formed.

The optical member 4B is made of a solid-state laser base material to which a luminescent center is added. The luminescent center added to the optical member 4B is a rare earth or transition metal that is excited by control light L_{C} having a control wavelength λ_{C} but is not excited by excitation light L_{P} having an excitation wavelength λ_{P}. For example, the optical member 4B is YAG (Yb:YAG) to which Yb is added. The optical member 4B is integrated with the optical member 4A by an adhesive, an optical contact, or surface-active bonding.

The volume diffraction grating 6D has a plurality of modified surfaces 6a. A method production method of the volume diffraction grating 6D is similar to the case of the volume diffraction grating 6 in the first embodiment. The volume diffraction grating 6D is formed to constitute the resonator 14 similarly to the volume diffraction grating 6A1 in a state (irradiation state) in which the optical element 2F is irradiated with the control light L_{C}. That is, the volume diffraction grating 6D functions as an output-side reflection unit of the resonator 14 in the irradiation state of the control light L_{c}.

The volume diffraction grating 6D is formed in the optical member 4B to which the luminescent center is added. Accordingly, as described in the optical element 2A, in a state where the control light L_{c} is not irradiated (non-irradiation state), the reflection characteristics and the like change from the irradiation state. Thus, the volume diffraction grating 6D does not have a function as the output-side reflection unit of the resonator 14 in the non-irradiation state of the control light L_{c}.

In one embodiment, the volume diffraction grating 6D preferably has an equivalent reflectance of 20% or more with respect to the laser beam L_{L} (a laser oscillation wavelength of a fundamental wave of the pulsed laser beam, preferably, harmonic wave) in the irradiation state, and the equivalent reflectance is preferably less than 20% in the non-irradiation state.

The heat sink 16, the optical member 4A, and the optical member 4B are integrated by an adhesive, an optical contact, or surface-active bonding.

A second light supply unit 26 includes a light source unit 26A that outputs control light L_{C} and a condensing optical system 26B that condenses the control light L_{C} to be incident on the optical member 4. FIG. 8 schematically illustrates the condensing optical system 26B as a lens. An example of the light source unit 26A is a semiconductor laser element.

In the laser system 10C, in a state where the second light supply unit 26 does not irradiate the optical element 2F with the control light L_{C} (non-irradiation state), the excitation light L_{P} is incident on the optical oscillator 24 from the first light supply unit 12. As a result, the optical member 4A which is a solid-state laser base material is excited to form an inversion distribution. At this time, since a transmittance of the laser beam L_{L} of the volume diffraction grating 6D is high, a loss as the resonator 14 is large. That is, a Q-value as a laser resonator is small, and laser oscillation is suppressed. At a stage where a sufficient inversion distribution is secured, the second light supply unit 26 irradiates the optical element 2F with the control light L_{C}. As a result, a reflectance of the volume diffraction grating 6D with respect to the laser beam L_{L} increases, and the resonator 14 is established. That is, the volume diffraction grating 6D of the optical element 2F functions as an output-side reflection unit of the resonator 14. As a result, laser oscillation occurs, and the laser system 10C outputs the laser beam L_{L}.

Accordingly, the laser beam L_{L} can be pulsed by a switching operation of the optical element 2F (switching control of the optical element 2F by the control light L_{C}) depending on whether or not the optical element 2 is irradiated with the control light L_{C}. As described in the first embodiment, the optical element 2F can perform a switching operation following a speed of light. Thus, the laser system 10C can output a short-pulsed laser beam. That is, in the laser system 10C, the optical element 2F functions as a Q-switch element.

In the optical member 4A of the optical element 2E, the volume diffraction grating 6C1 described in the third embodiment may be formed on an end surface 4b side. Reflection characteristics and the like of the volume diffraction grating 6C1 are similar to the case of the third embodiment.

A relationship between the irradiation state, the non-irradiation state, and the reflection (or transmission) characteristics in the optical element 2F may be opposite to the illustrated case. That is, the resonator 14 may be established when the optical element 2F is in the non-irradiation state, and the resonator 14 may not be established when the optical element 2F is in the irradiation state.

### (Modification 2)

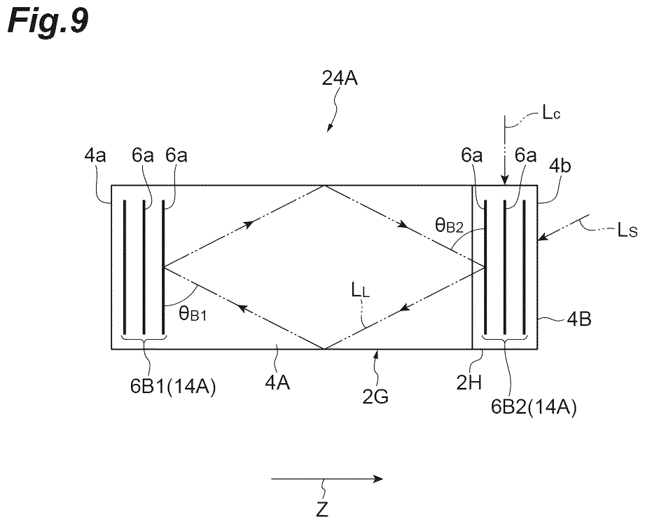

FIG. 9 is a schematic diagram illustrating a modification of the optical oscillator illustrated in FIG. 8. An optical oscillator 24A illustrated in FIG. 9 is different from the optical oscillator 24 in that an optical element 2G is provided instead of the optical element 2E and an optical element 2H is provided instead of the optical element 2F. In the optical oscillator 24A, a ring resonator 14A is formed by a volume diffraction grating 6B1 of the optical element 2G and a volume diffraction grating 6B2 of the optical element 2G in an irradiation state of control light L_{c}. Although not illustrated in FIG. 9, the optical oscillator 24A may have a heat sink 16 similarly to the optical oscillator 24.

The optical element 2G is different from the optical element 2E in that the volume diffraction grating 6B1 is formed in the optical member 4A instead of the volume diffraction grating 6A1. Since the optical member 4A is similar to the case of the optical element 2E, the description thereof is omitted.

The optical element 2H is different from the optical element 2F in that the volume diffraction grating 6B2 is formed in the optical member 4A instead of the volume diffraction grating 6D. Since the optical member 4B is similar to the case of the optical element 2F, the description thereof is omitted.

The volume diffraction grating 6B1 and the volume diffraction grating 6B2 form a ring resonator 14A in the irradiation state of the control light L_{C} similarly to the case of the optical element 2C (see FIG. 5).

That is, the volume diffraction grating 6B1 has a plurality of modified surfaces 6a and is designed to reflect a laser beam L_{L} incident at a blaze angle θ_{B1}. The volume diffraction grating 6B1 functions as an input-side reflection unit in the ring resonator 14A. The volume diffraction grating 6B2 has a plurality of modified surfaces 6a and is designed to reflect a laser beam L_{L} incident at a blase angle θ_{B2}. The volume diffraction grating 6B2 functions as an output-side reflection unit in the ring resonator 14A.

The volume diffraction grating 6B2 is formed in the optical member 4B to which a luminescent center is added. Accordingly, as described in the optical element 2A (or the optical element 2F), in a state where the control light L_{c} is not irradiated (non-irradiation state), reflection characteristics and the like change from the irradiation state. Thus, in the non-irradiation state of the control light L_{C}, the volume diffraction grating 6B2 does not have a function as the output-side reflection unit of the ring resonator 14A.

In one embodiment, the volume diffraction grating 6B2 preferably has an equivalent reflectance of 20% or more with respect to the laser beam L_{L} (a laser oscillation wavelength of a fundamental wave of the pulsed laser beam, preferably, harmonic wave) in the irradiation state, and the equivalent reflectance is preferably less than 20% in the non-irradiation state.

With the above configuration, in a case where the optical oscillator 24A is applied to the laser system 10C instead of the optical oscillator 24, the volume diffraction grating 6B1 and the volume diffraction grating 6B2 function as the ring resonator 14A in the irradiation state of the control light L_{c}. As a result, the laser beam L_{L} can be output. On the other hand, in the non-irradiation state of the control light Lc, since the volume diffraction grating 6B1 and the volume diffraction grating 6B2 do not function as the ring resonator 14A, the laser beam L_{L} is not output. Thus, the optical oscillator 24A has functions and effects similar to the optical oscillator 24. Further, the optical oscillator 24A includes the ring resonator 14A, and thus, it is possible to secure a resonator length while reducing a size of the optical oscillator 24A similarly to the case of the optical element 2C. Similarly to the case of the optical element 2C, seed light L_{S} may be incident from an outside of the optical element 2H. In a case where the seed light L_{S} is incident on the optical element 2H as described above, since the laser system including the ring resonator 14A can perform light injection synchronization with the laser beam, an oscillation wavelength and a phase thereof can be controlled.

The volume diffraction grating 6C1 described in the third embodiment may be formed in the optical member 4A or the optical member 4B. The reflection characteristics and the like of the volume diffraction grating 6C1 are similar to the case of the third embodiment.

A relationship between the irradiation state, the non-irradiation state, and the reflection (or transmission) characteristics in the optical element 2H may be opposite to the illustrated case. That is, the ring resonator 14A may be established when the optical element 2H is in the non-irradiation state, and the ring resonator 14A is not established when the optical element 2H is in the irradiation state.

### Sixth Embodiment

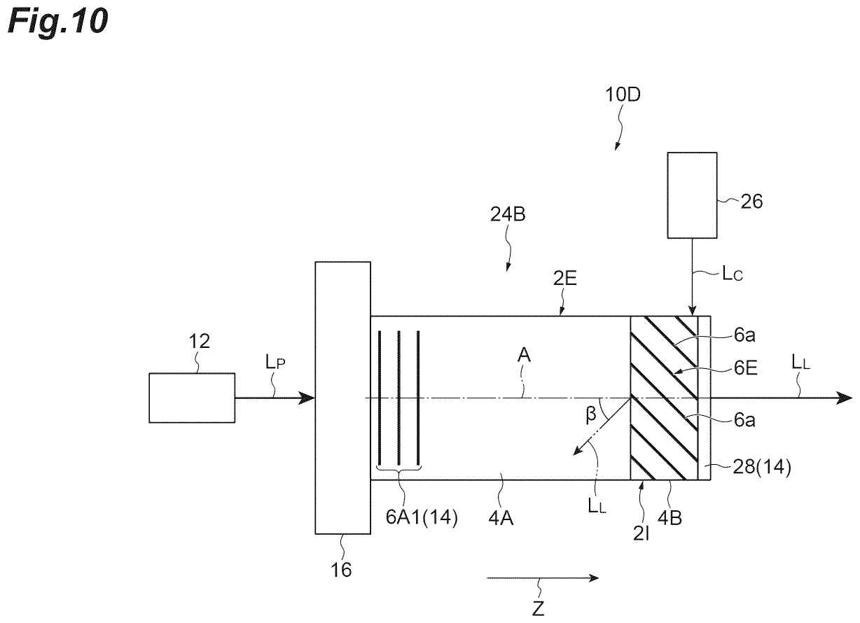

As a sixth embodiment, another example of the optical system including the optical element according to the present disclosure will be described. FIG. 10 is a schematic diagram of a laser system 10D which is an example of the optical system including the optical element.

The laser system 10D includes a first light supply unit 12, an optical oscillator 24B, and a second light supply unit 26. Since the first light supply unit 12 and the second light supply unit 26 are similar to the case of the laser system 10C, the description thereof is omitted.

The optical oscillator 24B is different from the optical oscillator 24 in that an optical element 2I is provided instead of the optical element 2F and a dielectric multilayer film 28 is provided. Thus, the optical oscillator 24B includes an optical element 2E, the optical element 2I, and the dielectric multilayer film 28. Since the optical element 2E of the optical oscillator 24B is similar to the case of the optical oscillator 24, the description thereof is omitted. The optical oscillator 24B may have a heat sink 16 similar to the case of the optical oscillator 24.

The dielectric multilayer film 28 is provided on a surface of the optical element 2I opposite to the optical element 2E. The dielectric multilayer film 28 has a partial reflectance that partially transmits a laser beam L_{L}. The dielectric multilayer film 28 constitutes a resonator 14 in the optical oscillator 24B together with a volume diffraction grating 6A1 of the optical element 2E.

The optical element 2I includes an optical member 4B and a volume diffraction grating 6E. That is, the optical element 2I is the optical member 4B in which the volume diffraction grating 6E is formed. Since the optical member 4B is similar to the case of the laser system 10C, the description thereof is omitted.

The volume diffraction grating 6E has a plurality of modified surfaces 6a. The volume diffraction grating 6E is formed to reflect the laser beam L_{L} in a direction of an angle β (β is an angle larger than 0) with respect to an optical axis A (a direction of the optical axis A corresponds to a Z direction) of a resonator 14 in a non-irradiation state of control light L_{C}. A method production method of the volume diffraction grating 6E is similar to the case of the volume diffraction grating 6.

The angle β may be an angle at which the laser beam L_{L} reflected at the angle β is completely deviated from an axis of the original laser beam L_{L} (laser beam incident on the volume diffraction grating 6E). For example, in a case where a laser beam diameter is d and a gain medium length is L_{GM}, the angle (reflection angle) β may satisfy a condition represented by the following formula.

$$[ Formula 9 ]$$

$$β \geq {tan}^{- 1} ( \frac{d}{2 {L}_{GM}} )$$

The laser beam L_{L} is reflected at such an angle β, and thus, the reflected laser beam L_{L} is completely deviated from the axis from the original laser beam L_{L}. Accordingly, efficient stimulated emission does not occur. Accordingly, laser oscillation can be suppressed by the control light Lc.

However, since a gain may be generated by actually reciprocating about 10 times, the angle β may be about 1/10 of the above formula.

In the volume diffraction grating 6E, in a case where a reflectance of the laser beam L_{L} in the non-irradiation state of the control light L_{C} is referred to as R_{OFF} and a transmittance of the laser beam L_{L} in the irradiation state of the control light L_{C} is referred to as T_{ON}, the R_{OFF} is 10% or more, preferably 90% or more, and T_{ON} is preferably more than 50% and more than 90%.

In the laser system 10D, in a case where the optical oscillator 24B is irradiated with excitation light L_{P} in the non-irradiation state of the control light L_{C}, the laser beam L_{L} is reflected by the volume diffraction grating 6E in the direction of the angle β. Thus, since a Q-value as a laser oscillator is low, laser oscillation is suppressed. At a stage where a sufficient inversion distribution is secured, the optical member 4B is irradiated with the control light L_{C}, and thus, the volume diffraction grating 6E becomes a transmission state with respect to the laser beam L_{L}. As a result, the resonator 14 is established, and the laser beam L_{L} is output. That is, the optical element 2I functions as a Q-switch element.

That is, the laser system 10D is a Q-switched laser system based on external control of the optical element 2I (specifically, the volume diffraction grating 6E) using the control light L_{C}. The optical element 2I corresponds to the optical element 2A, and has functions and effects similar to the optical element 2A. Thus, in the laser system 10D, it is possible to perform jitter control with accuracy close to rising.

A relationship between the irradiation state, the non-irradiation state, and the reflection characteristics in the optical element 2I may be opposite to the illustrated case. That is, the volume diffraction grating 6E may reflect the laser beam L_{L} at the angle β in the irradiation state of the optical element 2I, and the volume diffraction grating 6E may transmit the laser beam L_{L} in the non-irradiation state.

### Seventh Embodiment

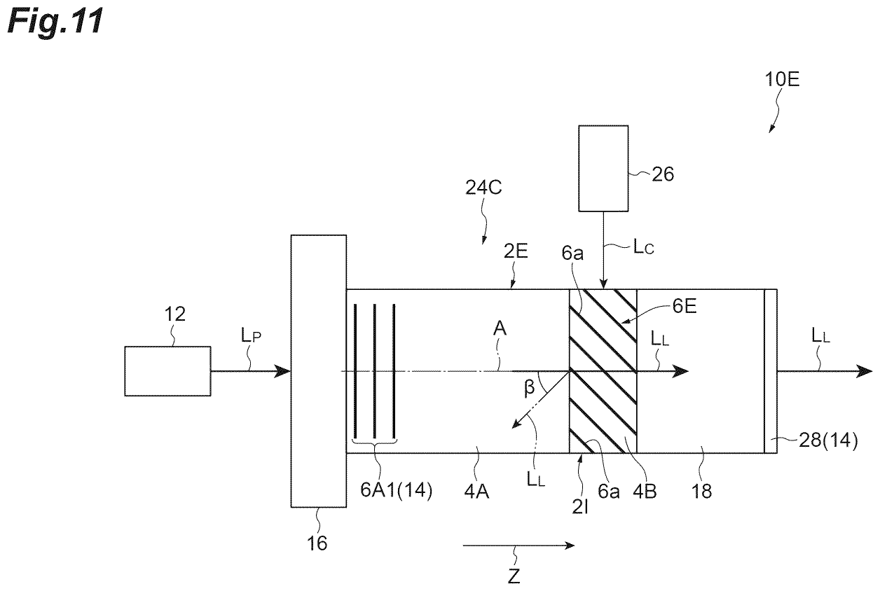

As a seventh embodiment, another example of the optical system including the optical element according to the present disclosure will be described. FIG. 11 is a schematic diagram of a laser system 10E which is an example of the optical system including the optical element.

The laser system 10E includes a first light supply unit 12, an optical oscillator 24C, and a second light supply unit 26. Since the first light supply unit 12 and the second light supply unit 26 are similar to the case of the laser system 10C, the description thereof is omitted.

The optical oscillator 24C is different from the optical oscillator 24B in that the optical oscillator 24C includes a saturable absorber 18, and a dielectric multilayer film 28 is provided on a surface of the saturable absorber 18 opposite to an optical element 2E. Thus, the optical oscillator 24C includes the optical element 2E, an optical element 2I, the saturable absorber 18, and the dielectric multilayer film 28. Since the optical element 2E and the dielectric multilayer film 28 of the optical oscillator 24C are similar to the case of the optical oscillator 24B, the description thereof is omitted. The saturable absorber 18 is similar to the saturable absorber 18 in the laser system 10A. The optical oscillator 24B may have a heat sink 16 similar to the case of the optical oscillator 24.

The optical element 2I includes an optical member 4B and a volume diffraction grating 6E similarly to the case of the optical oscillator 24B. That is, the optical element 2I is the optical member 4B in which the volume diffraction grating 6E is formed. Since the optical member 4B is similar to the case of the optical oscillator 24B, the description thereof is omitted. The volume diffraction grating 6E may be similar to the case of the optical oscillator 24B. In the optical oscillator 24C including the saturable absorber 18, a modulation amount of a transmittance between an irradiation state and a non-irradiation state, that is, a modulation amount between a transmittance Torr of a laser beam L_{L} in the non-irradiation state and a transmittance T_{ON} of the laser beam L_{L} in the irradiation state may be 5% or more.

In the laser system 10E, in a case where the optical oscillator 24B is irradiated with excitation light L_{P} in the non-irradiation state of control light L_{C}, the laser beam L_{L} is reflected by the volume diffraction grating 6E in a direction of an angle β. Thus, since a Q-value as a laser oscillator is low, laser oscillation is suppressed. At a stage where a sufficient inversion distribution is secured, the optical member 4B is irradiated with the control light L_{C}, and thus, the volume diffraction grating 6E becomes a transmission state with respect to the laser beam L_{L}. As a result, the resonator 14 is established, and the laser beam L_{L} is output. That is, the optical element 2I functions as a Q-switch element.

The laser system 10E is a Q-switched laser system based on external control of the optical element 2I (specifically, the volume diffraction grating 6E) using the control light L_{C}. The optical element 2I corresponds to the optical element 2A, and has functions and effects similar to the optical element 2A. Thus, in the laser system 10E, it is possible to perform jitter control with accuracy close to rising.

A relationship between the irradiation state, the non-irradiation state, and the reflection characteristics in the optical element 2I may be opposite to the illustrated case. That is, the volume diffraction grating 6E may reflect the laser beam L_{L} at the angle β in the irradiation state of the optical element 2I, and the volume diffraction grating 6E may transmit the laser beam L_{L} in the non-irradiation state.

### Eighth Embodiment

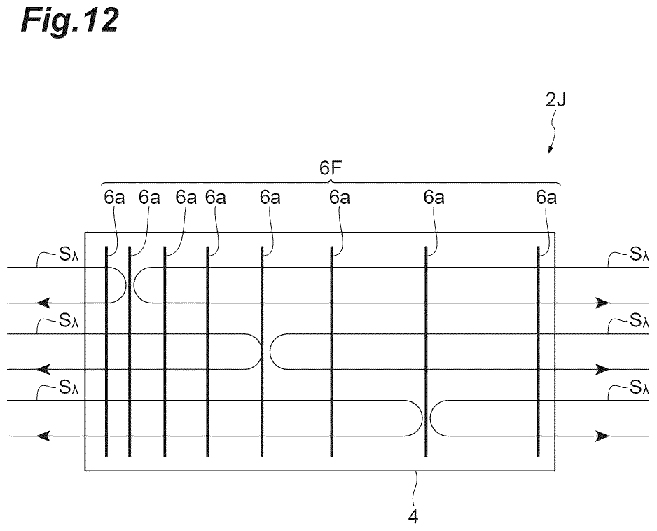

FIG. 12 is a schematic diagram illustrating an optical element according to an eighth embodiment. An optical element 2J illustrated in FIG. 12 is mainly different from the optical element 2 in that the optical element 2J includes a volume diffraction grating 6F having a chirp structure. The optical element 2J will be described focusing on this point.

The optical element 2J includes an optical member 4 and the volume diffraction grating 6F. That is, the optical element 2J is the optical member 4 in which the volume diffraction grating 6F is formed.

An example of a material of the optical member 4 is similar to the case illustrated in the first embodiment. In the eighth embodiment, the optical member 4 is, for example, crystal.

The volume diffraction grating 6F has a plurality of modified surfaces 6a. The volume diffraction grating 6F is different from the volume diffraction grating 6 in that the volume diffraction grating 6F has the chirp structure. That is, an interval (period) between the plurality of modified surfaces 6a is not a constant interval. A method for forming the volume diffraction grating 6F is similar to the case of the volume diffraction grating 6. The volume diffraction grating 6F may be designed as a diffraction grating having a high reflectance with respect to signal light S_{λ} having a spectral width Δλ. In this case, a period of the volume diffraction grating 6F is chirped in accordance with the spectral width Δλ. As a result, pulse compression or decompression of pulsed signal light S_{λ} can be performed.

The optical element 2J can be applied to an optical system such as a laser system as an element for the pulse compression or pulse decompression.

### Ninth Embodiment

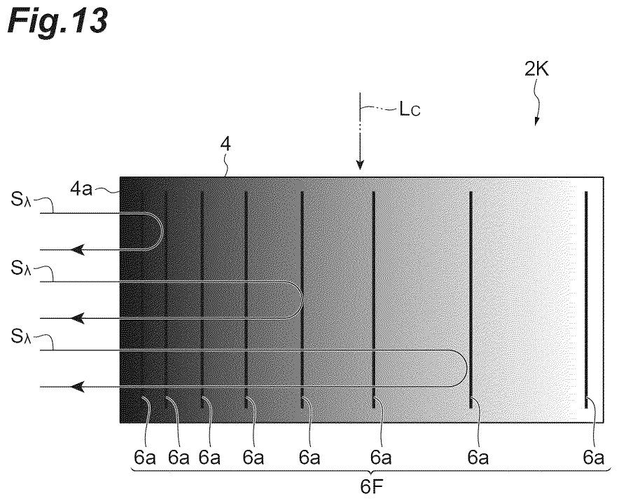

FIG. 13 is a schematic diagram illustrating an optical element according to a ninth embodiment. An optical element 2K illustrated in FIG. 13 is different from the optical element 2J in that a luminescent center is added to the optical member 4 similarly to the case of the optical element 2A.

In this case, reflection characteristics (or transmission characteristics) of the volume diffraction grating 6F change depending on whether or not the optical element 2K is irradiated with control light L_{C} similarly to the case of the optical element 2A. Accordingly, the optical element 2K can change a chirp amount by reflection of the volume diffraction grating 6F by switching between an irradiation state and a non-irradiation state of the control light L_{C} with respect to the optical element 2K.

The luminescent center may be uniformly dispersed in the optical member 4. For example, as schematically illustrated in gradation in FIG. 13, the luminescent center may be added in a predetermined distribution state (for example, a distribution state where an addition amount decreases from one end surface 4a to the other end surface 4b). As a result, in addition to the change in the chirp amount based on the irradiation state and the non-irradiation state of the control light L_{C} with respect to the optical element 2K, a change in the chirp amount based on the distribution of the luminescent center also occurs, and therefore, a larger chirp variable amount can be obtained.

The optical element 2K can be applied to an optical system such as a laser system as an element for the pulse compression or pulse decompression.

The present invention is not limited to various illustrated embodiments, but is intended to include the scope indicated by the claims and to include all modifications within the meaning and scope equivalent to the claims.

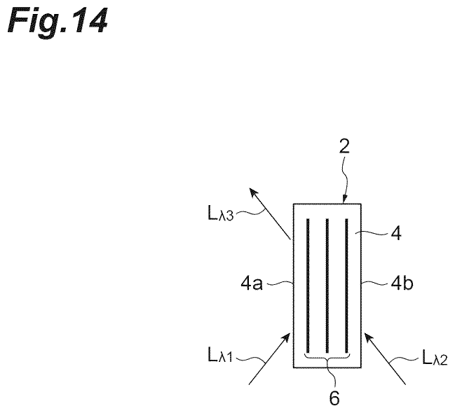

The optical element 2 can be used as, for example, an optical coupling element (or a beam coupling element) as illustrated in FIG. 14. Specifically, light L_{λ1} having a wavelength λ₁ that is a Bragg wavelength λ_{B} in the volume diffraction grating 6 formed in the optical member 4 is incident on the optical element 2 from the end surface 4a. At this time, light L_{λ2} having a wavelength λ₂ deviated from a band Δλ (band that can be reflected by the volume diffraction grating 6) of the wavelength Δ1 (Bragg wavelength λ_{B}) is incident on the optical element 2 from the end surface 4b side coaxially with a reflection direction of the light L_{λ1}. As a result, it is possible to obtain light L_{λ3} having a wavelength λ₁ and a wavelength λ2 obtained by combining the light La reflected by the volume diffraction grating 6 and the light L_{λ2} transmitted through the volume diffraction grating 6. In a case where the luminescent center is added to the optical member 4 as in the optical element 2A, switching between a case where optical coupling is performed and a case where optical coupling is not performed can be performed depending on whether or not the optical element 2A is irradiation with the control light L_{C}.

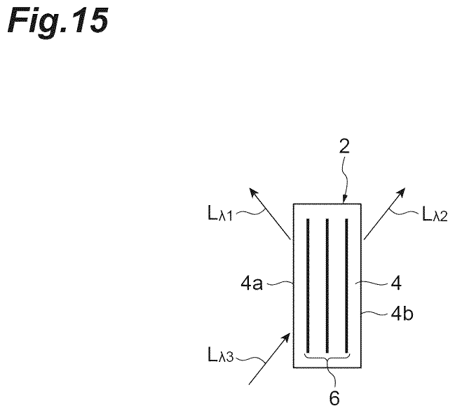

The optical element 2 can be used as, for example, a spectral filter as illustrated in FIG. 15. Specifically, the light L_{λ3} having the wavelength λ1 that is the Bragg wavelength λ_{P} in the volume diffraction grating 6 formed in the optical member 4 and the wavelength 22 is incident on the optical element 2 from the end surface 4a. At this time, the light L_{λ1} having the wavelength λ1 (Bragg wavelength λ_{B}) is reflected by the volume diffraction grating 6, and the light L_{λ2} having the wavelength λ2 is transmitted through the volume diffraction grating 6. As a result, the light L_{λ3} having the wavelength λ1 and the wavelength λ2 can be separated into the light L_{λ1} having the wavelength λ1 and the light L_{λ2} having the wavelength λ2. In a case where the luminescent center is added to the optical member 4 as in the optical element 2A, it is possible to switch between the presence and absence of a filtering function of the optical element 2 depending on whether the optical element 2A is irradiated with the control light L_{C}.

When the volume diffraction grating 6 is designed to reflect only light incident at the blase angle θ_{B}, only a component within an angle that can be reflected about the blase angle θ_{B} of light incident on the optical element 2 is reflected, and a component incident at an angle exceeding the angle that can be reflected about the blase angle θ_{B} is transmitted. Accordingly, the optical element 2 also functions as an element that filters a lateral mode of light (for example, a laser beam) incident on the optical element 2. In a case where the luminescent center is added to the optical member 4 as in the optical element 2A, the filtering function of the optical element 2 can be controlled depending on whether or not the optical element 2A is irradiated with the control light L_{C}.

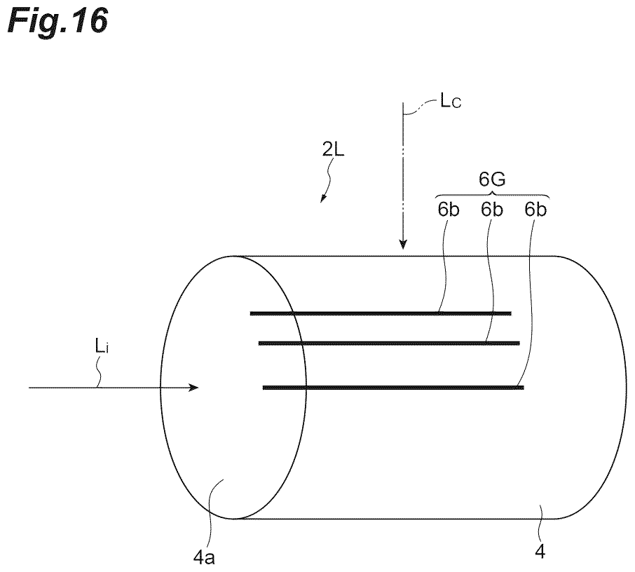

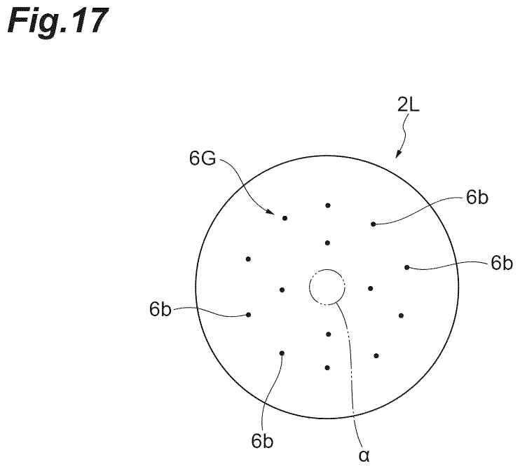

Each of the plurality of modified regions of the optical element is not limited to a planar region like the illustrated modified surface. As in the optical element illustrated in FIGS. 16 and 17, each modified region may be a linear region. FIG. 16 is a schematic diagram illustrating still another modification of the optical element. FIG. 17 is a diagram in a case where the optical element illustrated in FIG. 16 is viewed from an incident side of the excitation light L_{P} illustrated in the drawing. In FIGS. 16 and 17, the modified region is indicated by a thick solid line as in the other drawings. In FIG. 17, a region α surrounded by a dashed double-dotted line schematically illustrates a region where light propagates with in the optical element.

An optical element 2L illustrated in FIGS. 16 and 17 is different from the optical element 2A illustrated in FIG. 3 in that the optical element 2L includes a volume diffraction grating 6G instead of the volume diffraction grating 6. The optical element 2L includes an optical member 4 and a volume diffraction grating 6G. The optical member 4 is a member similar to the optical member 4 of the optical element 2A illustrated in FIG. 2, and is an optical member to which a luminescent center excited by control light L_{C} is added. In FIG. 16, a circular columnar optical member 4 is illustrated.

The volume diffraction grating 6G has a plurality of modified regions 6b. Each modified region 6b extends in a direction intersecting an end surface 4a on which light Lᵢ (for example, laser beam) is incident. In one form illustrated in FIG. 16, each modified region 6b is orthogonal to the end surface 4a. The plurality of modified regions 6b are formed by the volume diffraction grating 6G including the modified regions 6b to be able to propagate through the optical member 4 while reflecting the light Lᵢ. In the form illustrated in FIGS. 16 and 17, the light Lᵢ is incident along a central axis of the circular columnar optical member 4, and the plurality of modified regions 6b are disposed around the central axis. Similarly to the case of the optical element 2A, the reflection characteristics of the volume diffraction grating 6G change depending on whether or not there is the control light L_{C}. Thus, for example, in a case where the optical element 2L (or the optical member 4) is disposed within an optical resonator (a case where a dielectric multilayer film constituting the optical resonator is formed on the end surface 4a of the optical member 4 and an end surface 4b opposite thereto), an oscillation mode can be controlled by switching between the irradiation state and the non-irradiation state of the control light L_{C}.

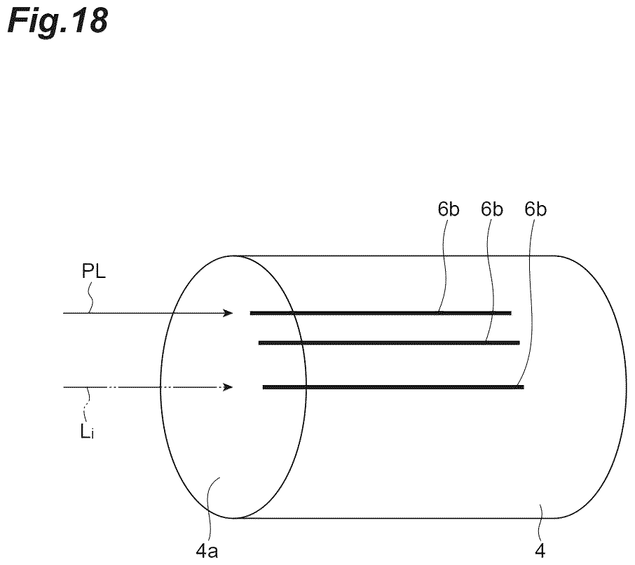

The optical element 2L is produced similarly to the production method described with reference to FIG. 2 except that the incident position of the pulsed laser beam PL on the optical member 4 is different and the modified region 6b is formed in a linear shape. Specifically, as illustrated in FIG. 18, the optical element 2L can be formed by irradiating the optical member 4 with the pulsed laser beam PL from the end surface 4a on which the excitation light L_{P} is to be incident.

Similarly to the case of the optical member 4 of the optical element 2 illustrated in FIG. 1, the luminescent center excited by the control light L_{C} may not be added to the optical member 4 of the optical element 2L.

The various embodiments, modifications, and the like described above may be appropriately combined without departing from the gist of the invention.

### REFERENCE SIGNS LIST

2, 2A, 2B, 2C, 2D, 2E, 2F, 2G, 2H, 2I, 2J, 2K, 2L optical element
4,4A, 4B optical member
6 volume diffraction grating
6a modified surface (modified region)
6b modified region
10, 10A, 10B, 10C, 10D, 10E laser system (optical system)
6A1 volume diffraction grating
6A2 volume diffraction grating
6B1 volume diffraction grating
6B2 volume diffraction grating
6C1 volume diffraction grating
6D volume diffraction grating
6E volume diffraction grating
6F volume diffraction grating
14 resonator
14A ring resonator
24, 24A, 24B, 24C optical oscillator (optical system)
A optical axis.

1. An optical element comprising:
a first optical member made of a single crystal, ceramics, or glass, wherein
a first diffraction grating configured to reflect light having a predetermined wavelength is formed in the first optical member, and
the first diffraction grating is a volume holographic diffraction grating or a volume Bragg diffraction grating formed by a plurality of modified regions in which a part of the first optical member is modified.

2. The optical element according to claim 1, wherein
each of the plurality of modified regions is a planar or linear region.

3. The optical element according to claim 1, wherein
a second diffraction grating constituting a resonator together with the first diffraction grating is formed in the first optical member, and
the second diffraction grating is a volume holographic diffraction grating or a volume Bragg diffraction grating formed by a plurality of modified regions in which a part of the first optical member is modified.

4. The optical element according to claim 3, wherein
the resonator is a ring resonator.

5. The optical element according to claim 1, wherein
the first optical member is a solid-state laser base material.

6. The optical element according to claim 1, wherein
the first diffraction grating has a chirp structure.

7. The optical element according to claim 1, wherein
a luminescent center excited by control light is added to the first optical member.

8. An optical system comprising the optical element according to claim 1.

9. An optical system comprising:
the optical element according to claim 1; and
a second optical member made of a single crystal, ceramics, or glass, a luminescent center excited by control light being added to the second optical member, wherein
a second diffraction grating forming a resonator together with the first diffraction grating configured to reflect the light having the predetermined wavelength in a non-irradiation state where the first optical member is not irradiated with the control light or an irradiation state where the first optical member is irradiated with the control light is formed in the second optical member, and
the second diffraction grating is a volume holographic diffraction grating or a volume Bragg diffraction grating.

10. The optical system according to claim 9, wherein
the resonator is a ring resonator.

11. An optical system comprising:
a plurality of optical members made of a crystal, ceramics, or glass, wherein
the plurality of optical members are disposed along one direction,
a first diffraction grating configured to reflect light having a predetermined wavelength is formed in a first optical member among the plurality of optical members, and
the first diffraction grating is a volume holographic diffraction grating or a volume Bragg diffraction grating formed by a plurality of modified regions in which a part of the first optical member is modified.

12. The optical system according to claim 11, wherein
the first optical member is a solid-state laser base material, a heat sink, or a saturable absorber.

13. The optical system according to claim 11, wherein
the first optical member is a solid-state laser base material,
a second diffraction grating constituting a resonator together with the first diffraction grating is formed in the first optical member, and
the second diffraction grating is a volume holographic diffraction grating or a volume Bragg diffraction grating formed by a plurality of modified regions in which the first optical member is modified.

14. The optical system according to claim 11, wherein
the first optical member is a solid-state laser base material,
a luminescent center excited by control light is added to a second optical member among the plurality of optical members, and a second diffraction grating constituting a resonator together with the first diffraction grating is formed in the second optical member, and
the second diffraction grating is a volume holographic diffraction grating or a volume Bragg diffraction grating.

15. An optical system including a solid-state laser base material and a resonator, and configured to output a laser beam, the system comprising:
an optical member disposed within the resonator, and made of a crystal, ceramics, or glass, wherein
a luminescent center excited by control light is added to the optical member, and a diffraction grating configured to reflect the laser beam in a direction different from an optical axis of the resonator in a non-irradiation state where the optical member is not irradiated with the control light or an irradiation state where the optical member is irradiated with the control light is formed in the optical member, and
the diffraction grating is a volume holographic diffraction grating or a volume Bragg diffraction grating formed by a plurality of modified regions in which a part of the optical member is modified.

16. A method for producing an optical element comprising:
a step of forming a volume holographic diffraction grating or a volume Bragg diffraction grating configured to reflect light having a predetermined wavelength in an optical member made of a single crystal, ceramics, or glass, wherein
the volume holographic diffraction grating or the volume Bragg diffraction grating is formed by modifying the optical member by using a pulsed laser beam.

17. The method for producing an optical element according to claim 16, wherein
a pulse width of the pulsed laser beam is 0.1 ps to 1 ns.

18. The method for producing an optical element according to claim 16, wherein
a pulse width of the pulsed laser beam is 1 ps to 1 ns.

19. The method for producing an optical element according to claim 16, wherein
the pulsed laser beam is incident on a first surface of the optical member on which the pulsed laser beam is incident from a perpendicular direction of the first surface.

20. The method for producing an optical element according to claim 16, wherein
the pulsed laser beam is incident on a first surface of the optical member on which the pulsed laser beam is incident from an oblique direction with respect to a perpendicular direction of the first surface.

21. The method for producing an optical element according to claim 16, wherein
the volume holographic diffraction grating or the volume Bragg diffraction grating is formed by a plurality of modified regions by the pulsed laser beam, and
each of the plurality of modified regions is formed in a planar or linear shape.

22. The method for producing an optical element according to claim 16, wherein
a first surface of the optical member on which the pulsed laser beam is incident is a surface different from a second surface of the optical member on which the light having the predetermined wavelength is incident.

23. The method for producing an optical element according to claim 16, wherein
a first surface of the optical member on which the pulsed laser beam is incident is the same surface as a second surface of the optical member on which the light having the predetermined wavelength is incident.
